(19) United States
(12) Patent Application Publication
(10) Pub. No.: US 2013/0034249 A1
(43) Pub. Date: Feb. 7, 2013

(54) SOLID STATE AUDIO POWER AMPLIFIER

(71) Applicant: Bruce Keir, Northhampton (GB)

(72) Inventor: Bruce Keir, Northhampton (GB)

(21) Appl. No.: 13/564,310

(22) Filed: Aug. 1, 2012

(30) Foreign Application Priority Data
Aug. 3, 2011 (GB) 1113433.5

(51) Int. Cl. H03F 99/00

(52) U.S. Cl. 381/120

(57) ABSTRACT

A solid-state audio power amplifier providing an instantaneous maximum output voltage capability in excess of its long term power output capability, in which the input signal is supplied from analogue or digital signal processor. The signal processor is arranged to limit the long term power output of the solid-state amplifier in a non-linear amplitude and frequency dependant manner

This invention relates to the combination of a solid state audio power amplifier and signal processing means for use with an electric guitar amplifier.

It is well known and accepted by the practising electric guitarist, that a guitar amplifier using thermionic valves (also referred to as ‘tubes’) as the primary power amplification devices will be perceived by the user to sound significantly louder than a guitar amplifier of an equivalent power output rating utilising solid state power amplification devices. Additionally, a valve power amplifier will possess desirable frequency response variations, and, when driven to full power output, will produce non-linear amplitude and frequency domain distortions that are also deemed desirable by the practising musician and listener, and which are not produced by current state of the art solid state linear audio power amplifiers.

To overcome the perceived lack of volume, and the lack of both the desirable frequency response characteristics and the desirable amplitude distortion characteristics provided by a valve audio power amplifier when compared to a conventional solid-state power amplifier of the same nominal power rating, one aspect of this invention provides a combination of signal processing means and a solid state audio power amplifier and associated power supply, whose maximum output voltage before limiting is controlled in a frequency dependant manner such that the maximum RMS power delivered to an associated guitar loudspeaker system, is equivalent to that of a conventional valve power amplifier of an equivalent RMS power rating.

It is well known and accepted by the users of guitar amplifiers that utilise thermionic valves (also known as ‘Tubes’) as the means to obtain audio power amplification, that a valve amplifier will produce a higher sound pressure level when used in conjunction with a guitar loudspeaker system than a solid state (transistorised) audio amplifier of an equivalent nominal power output rating.

Over time, various explanations have been suggested for this phenomenon, all tending to be based around the vague notional concept of psycho-acoustics. It has been suggested that the inherent non-linearity in the electrical input/output transfer characteristic of a thermionic valve, and the resultant addition of harmonically related distortion components to the output signal that are not present in the original input signal, has the effect of allowing the user and/or listener of the valve amplifier, when used in conjunction with a guitar loudspeaker system, to perceive the sound pressure level of such an amplifier to be greater than it is in reality.

This is not the case, and the fundamental cause for the increased sound pressure level of the system can be shown by a straightforward engineering analysis of a conventional valve power amplifier driving a typical musical instrument type loudspeaker system.

Some embodiments of the invention will now be described by way of example with reference to the accompanying drawings in which:

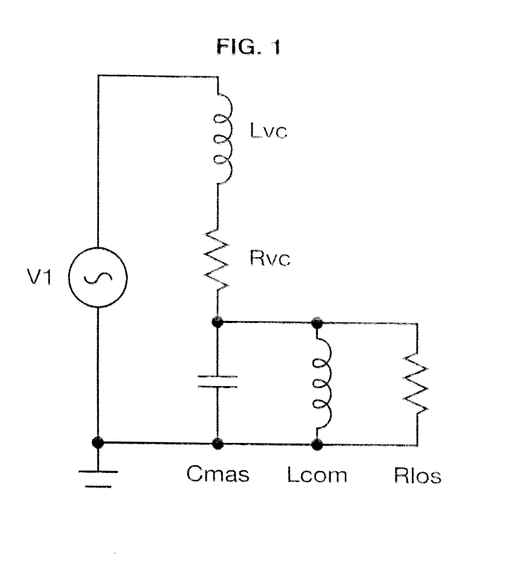

FIG. 1:—Loudspeaker system electrical model equivalent schematic, driven from a voltage source.

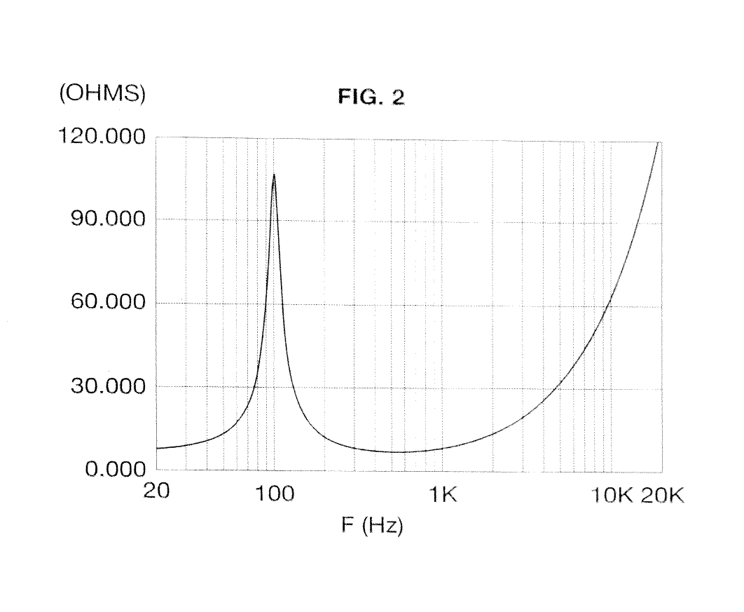

FIG. 2:—Impedance of loudspeaker system electrical equivalent schematic model versus frequency response plot of system depicted in FIG. 1.

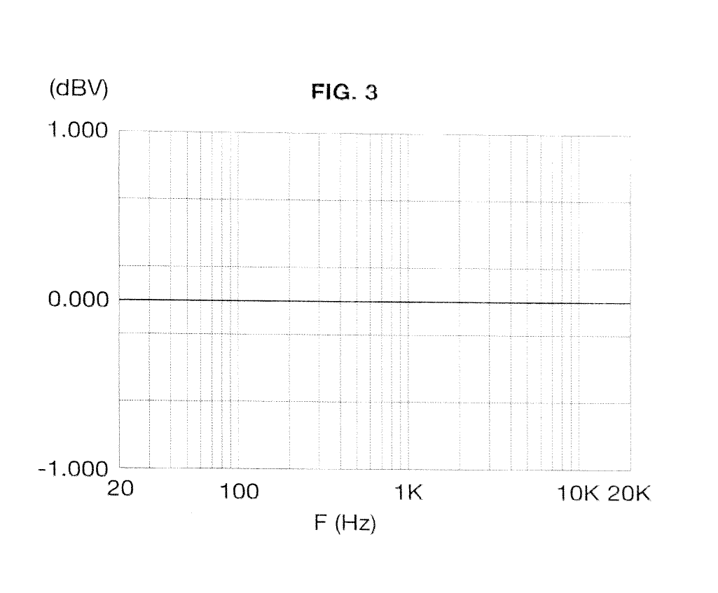

FIG. 3:—Loudspeaker system electrical model schematic terminal voltage frequency response plot of system depicted in FIG. 1.

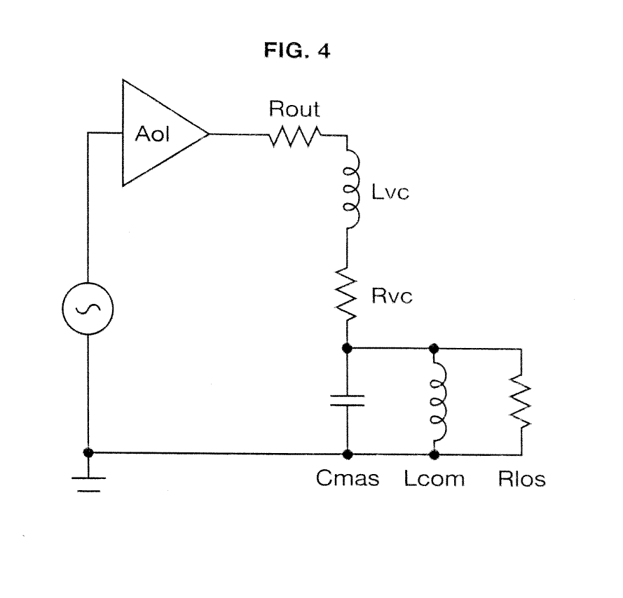

FIG. 4:—Loudspeaker system electrical model equivalent schematic connected to the output of a audio power amplifier with voltage gain ‘Aol’ and output resistance ‘Rout’.

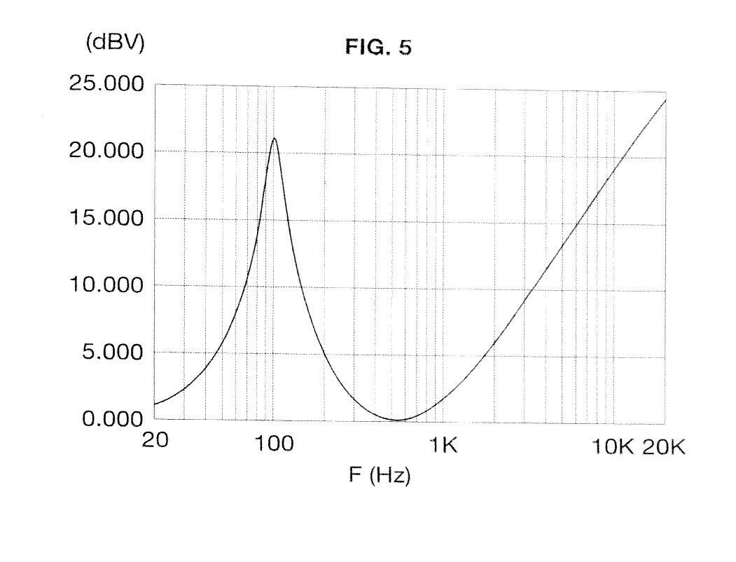

FIG. 5:—Loudspeaker system electrical model equivalent schematic terminal voltage frequency response plot of system in FIG. 4.

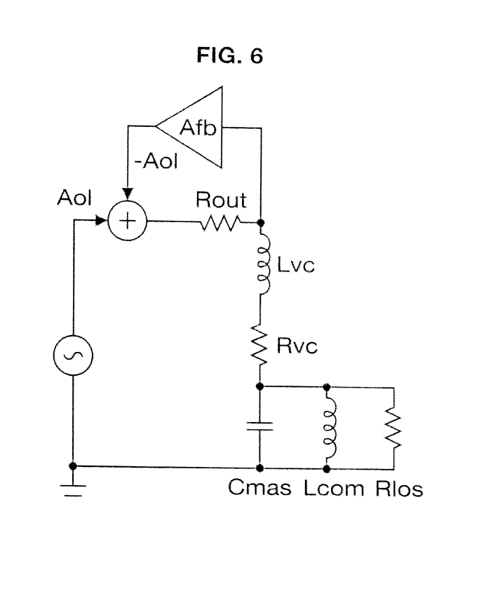

FIG. 6:—Loudspeaker system electrical equivalent model schematic driven from a audio power amplifier with voltage gain ‘Aol’ and output resistance ‘Rout’, with negative feedback factor ‘Afb’ applied to the power amplifier.

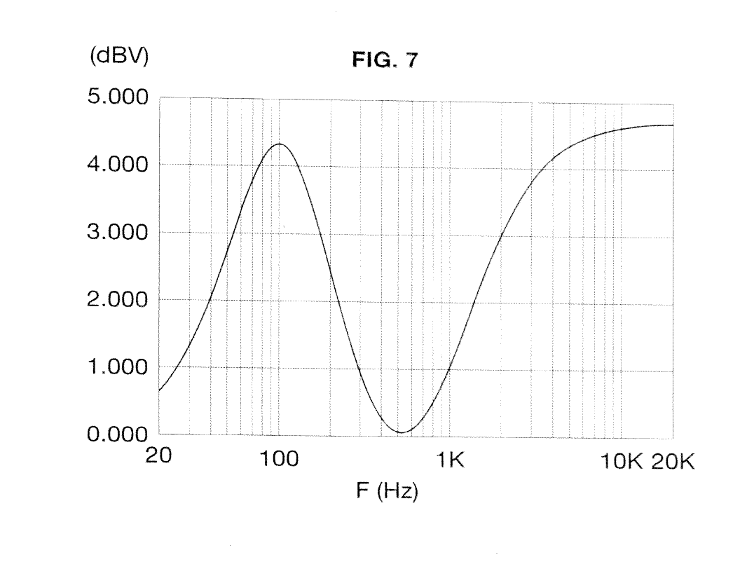

FIG. 7:—Loudspeaker system electrical model equivalent schematic terminal voltage frequency response plot of system in FIG. 6.

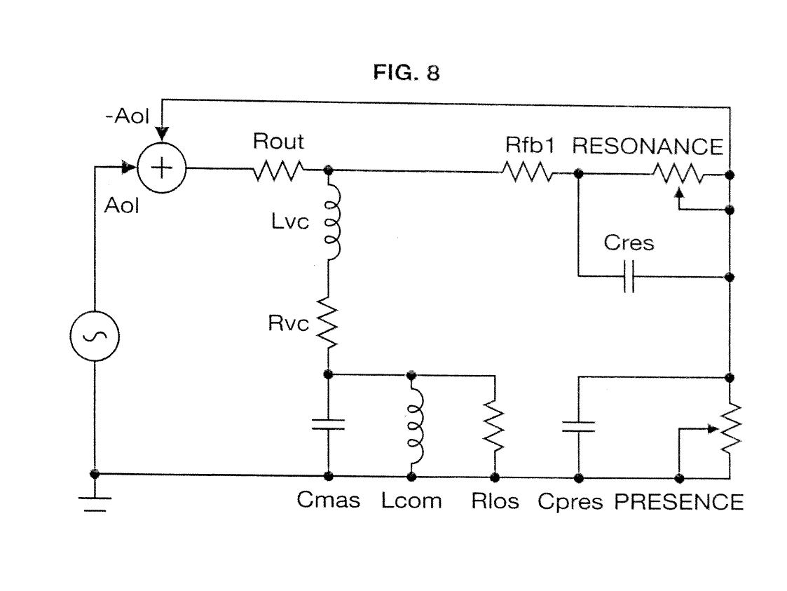

FIG. 8:—Loudspeaker system electrical model equivalent schematic driven from a audio power amplifier with voltage gain ‘Aol’ and output resistance ‘Rout’, with negative feedback applied to the power amplifier via frequency selective low-pass and high-pass ‘PRESENCE’ and ‘RESONANCE’ controls in the negative feedback loop.

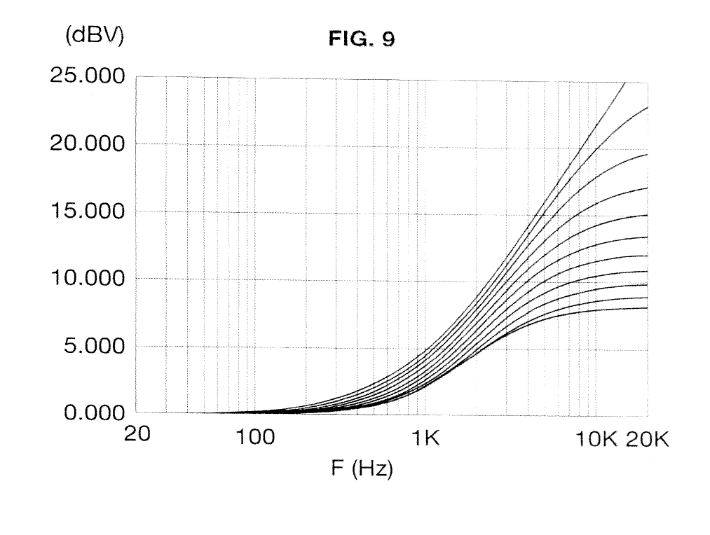

FIG. 9:—Loudspeaker system electrical equivalent model schematic terminal voltage frequency response plot of system in FIG. 8, for various settings of the ‘PRESENCE’ control.

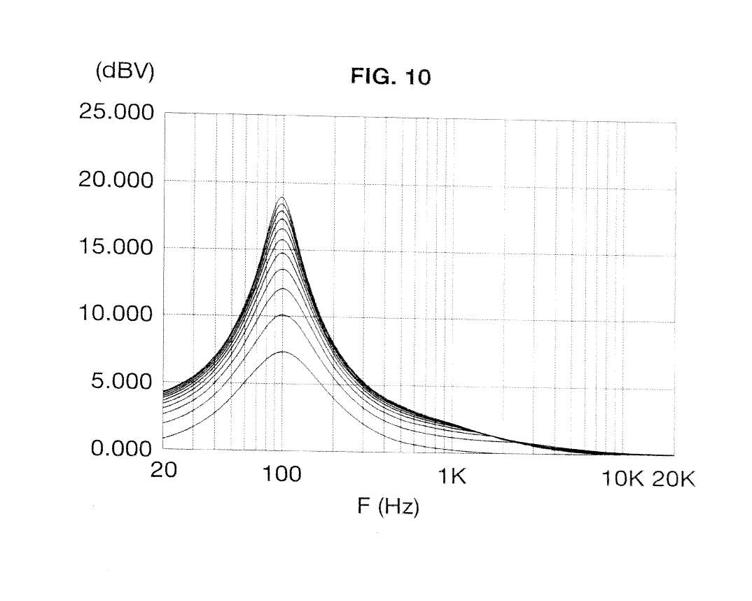

FIG. 10:—Loudspeaker system electrical model equivalent schematic terminal voltage frequency response plot of system in FIG. 8, for various settings of the ‘RESONANCE’ control.

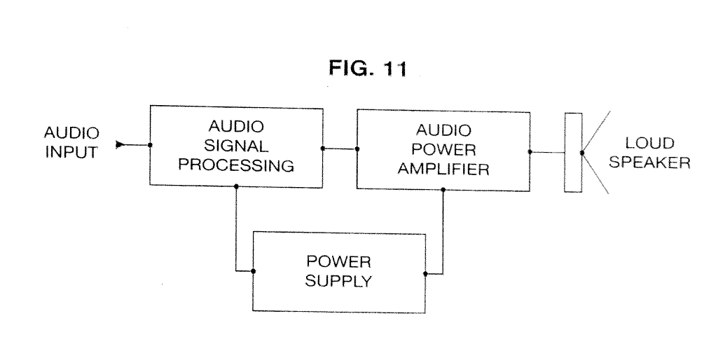

FIG. 11:—Shows the general arrangement of a digital signal processing unit according to the invention, arranged to receive and process an audio input signal, with the processed signal output connected to a audio power amplification stage, in turn driving a loudspeaker.

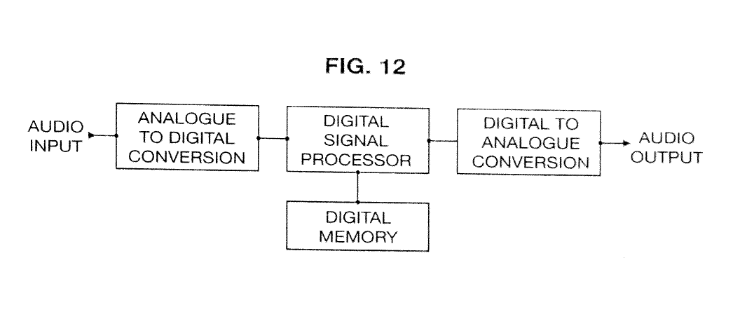

FIG. 12:—Depicts in greater detail the digital signal processing unit of FIG. 11, with analogue to digital conversion means to receive an audio input signal and digital to analogue conversion means to output an audio signal, to and from respectively, the digital signal processing unit. Also illustrated is digital memory means for the storage of audio data, filter coefficients and program code, as required by the digital signal processing unit.

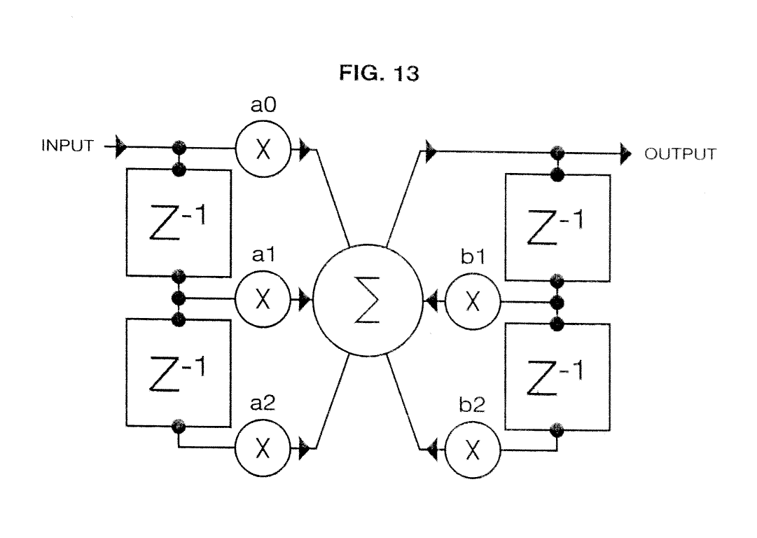

FIG. 13:—Illustrates the numerical signal process flow for a typical infinite impulse response (IIR) digital filter.

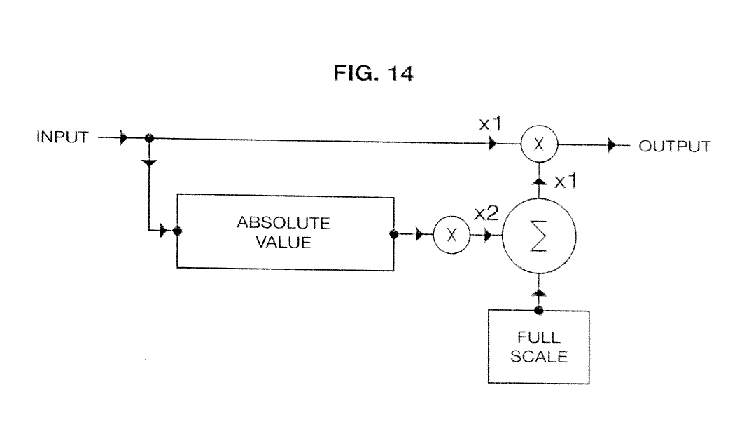

FIG. 14:—Illustrates the numerical signal flow for an amplitude domain, non-linear, harmonic distortion generating, and signal limiting, digital signal processing block.

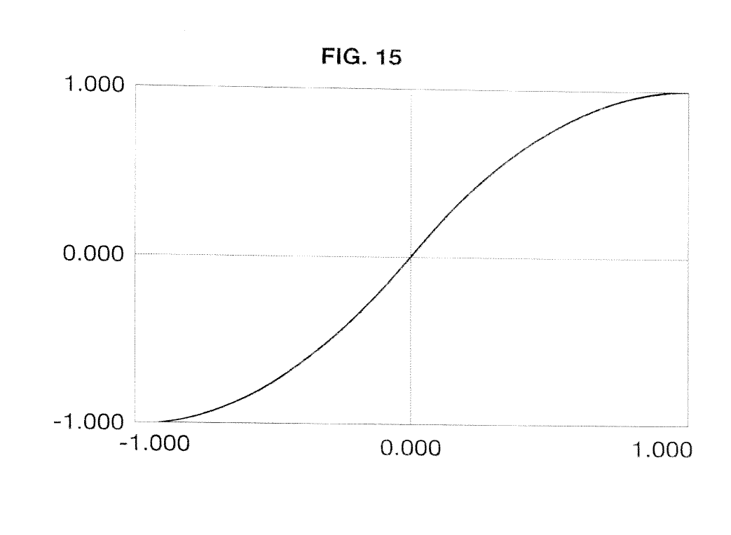

FIG. 15:—Illustrates the input-output transfer function of the amplitude domain non-linear transfer function depicted in FIG. 14.

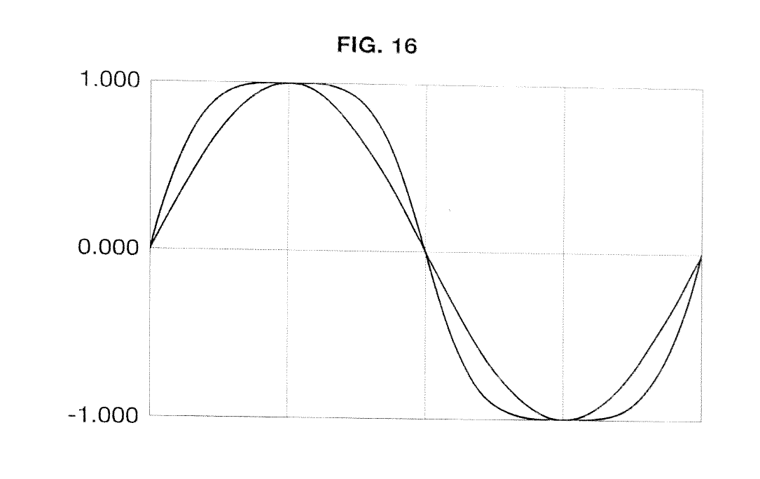

FIG. 16:—Illustrates the output waveform of the amplitude domain non-linear transfer function depicted in FIG. 14 in response to a sinusoidal input signal.

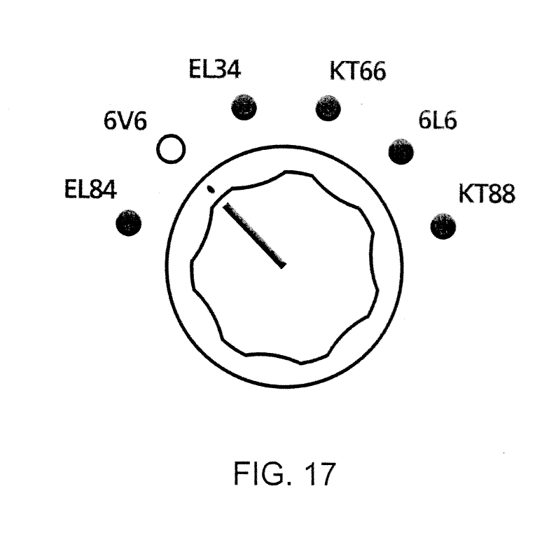

FIG. 17:—Illustrates a control selector knob for selecting output characteristics corresponding to various types of thermionic valves.

FIG. 1 shows the electrical equivalent circuit representing a conventional moving-coil loudspeaker drive unit enclosed in a sealed box loudspeaker cabinet, such as is typical for a guitar amplification system.

Rvc represents the electrical resistance of the loudspeaker voice coil, and Lvc represents the inductance of the voice coil formed by winding the voice coil around the loudspeaker iron pole-piece. Lcom and Cmas represent respectively the compliance and mass of the loudspeaker cone and the air load enclosed inside the loudspeaker enclosure, whilst RIos represents the combined losses of both the mechanical loudspeaker system and the air enclosed inside the loudspeaker cabinet.

Using the electrical circuit equivalent of a guitar loudspeaker enclosure system, the terminal impedance of the driver and enclosure system can be plotted as a function of frequency, as shown in FIG. 2. Although loudspeaker drive units and systems are quoted by convention to have a nominal impedance value (typically 4, 8 or 16 Ohms), it can be seen from reference to FIG. 2, that the system impedance varies by a large degree dependant on the frequency of the excitation signal being applied to the system, with a resonant peak in the lower frequency region due to the mechanical system resonance formed by the loudspeaker drive unit and the air load inside the loudspeaker enclosure. The rise in system impedance at higher frequencies is due to the inductive nature of the loudspeaker drive unit voice coil. It can be further noted from FIG. 2, that the ratio of the lowest to the highest system impedance through the audio frequency range is typically in excess of 10:1.

Referring again to FIG. 1, Voltage source V1 is assumed by convention to have negligible or zero source impedance, such as is the case with contemporary solid state audio power amplifier design, and it is therefore apparent that the voltage across the loudspeaker system terminals will be independent of the frequency of the signal applied to the loudspeaker voice coil terminals. This is depicted in FIG. 3.

Now consider the case where the loudspeaker system is being driven from an amplifier with a voltage gain of ‘Aol’ and with an intrinsic, non-zero, output resistance ‘Rout’, as depicted in FIG. 4. It can be seen by inspection that the combination of the loudspeaker system impedance and the amplifier output resistance form a potential divider across the amplifier output terminals, with Rout forming the upper element of the potential divider, and the loudspeaker electrical system constituting the lower element of the potential divider. Due to the frequency dependant magnitude of the impedances of the various loudspeaker electrical equivalent circuit elements, the voltage across the loudspeaker system terminals now becomes highly dependent upon the frequency of the signal being applied to the combined amplifier and loudspeaker system, and this voltage will vary according to the frequency of the signal applied to the input of the combined amplifier and loudspeaker system. This is illustrated in FIG. 5, which shows the loudspeaker terminal voltage for a typical Celestion G12-75 twelve inch guitar loudspeaker drive unit mounted in a sealed enclosure of 40 Litres, when driven from a valve audio power amplifier typical source impedance of 100 ohms. It can be observed that there is a variation in excess of twenty decibels in the voltage developed across the loudspeaker system terminals through the range of the audio spectrum. Under normal linear loudspeaker drive unit operating conditions, the sound pressure level produced by a moving coil loudspeaker system is directly proportional to the terminal voltage applied to the loudspeaker, and there will therefore be a corresponding variation in the sound pressure level produced by the loudspeaker system. Such variation in sound pressure level contrasts markedly with the case of the system response depicted in FIG. 3.

Valve audio power amplifiers almost invariably utilise pentode (five electrode) or tetrode (four electrode) devices as the active power amplification devices. Typical examples of audio power pentodes are types EL34 and EL84, with types KT88, 6550 and 6L6 being examples of typical beam tetrodes. Both types of device are characterised by a transfer function that closely approximates that of a voltage controlled current source, and by direct implication, this infers a characteristic high output resistance to the device. By ensuring that the maximum output current capability of the particular valve type utilised in a power amplifier is not exceeded, the maximum output voltage capability of a valve amplifier is then set by the value of the load resistance that the valve amplifier is connected to. Referring again to FIG. 4, it can be seen that the maximum voltage applied by a valve amplifier to typical loudspeaker system will be highest at the fundamental low frequency resonance of the loudspeaker and at high frequencies where the inductance of the voice coil forms a significant part of the total magnitude of the loudspeaker load impedance.

This characteristic rise in maximum, undistorted, peak voltage delivery capability of a valve power amplifier, at the frequency dependant higher values of the loudspeaker system characteristic impedance is the fundamental reason that a valve audio power amplifier will sound louder than a conventional solid state power amplifier of an equivalent stated nominal power rating.

It s also noted that over the range of frequencies where the magnitude of the loudspeaker system impedance rises above the nominal impedance of the loudspeaker system, the power delivered by the amplifier, and dissipated in the loudspeaker load, falls. As a direct consequence, the power input requirement to the amplifier, as supplied by the power supply unit, will also fall.

The use of negative feedback in audio power amplifiers, both valve and solid state, is well known and brings many conventional advantages, including the reduction of harmonic distortion, increased bandwidth, and a lowering in system output impedance. All these advantages are conventionally deemed to be desirable, and it is understood that these advantages are obtained at the expense of total system closed loop gain.

FIG. 6 depicts the same arrangement as in FIG. 4, but with the addition of a negative feedback path, provided by subtracting a fraction of the output signal generated by the system, Afb, from the input signal applied to the system. FIG. 7 shows the resultant loudspeaker terminal frequency response of the combined power amplifier, loudspeaker electrical load and feedback system. It can be immediately observed from the frequency response curve that the variation in amplitude response across the audio frequency range is much reduced as a consequence of the application of the negative feedback signal.

By introducing frequency selective filtering into the negative feedback path of an amplifier, the amplitude response of the amplifier can be made to be frequency dependant. In 1954 Leo Fender(Fender Musical Instruments) introduced a variable cut-off frequency low-pass filter into the feedback path of a valve power amplifier, with the amount of feedback and the frequency at which the low-pass filtering is introduced being adjustable via a front panel control, which he termed ‘Presence’. Many other amplifier designs subsequently copied this feature, and later a similar control named ‘Resonance’, to allow control of the low frequency response of a power amplifier by high-pass filtering of the power amplifier feed-back signal, was introduced on many guitar amplifier designs.

FIG. 8 depicts the general arrangement of FIG. 6, but with the inclusion of the frequency selective feedback low-pass and high-pass filtering arrangements just described. Capacitor ‘Cres’ and the user adjustable control potentiometer ‘RESONANCE’ perform the high-pass filtering function, whilst capacitor ‘Cpres’ and the user adjustable control potentiometer ‘PRESENCE’ form the low-pass filtering function.

FIG. 9 denotes how the high frequency amplitude response of the combined power amplifier, the associated loudspeaker load, and the negative feedback network varies as the Presence control is rotated from minimum to maximum. (Note that by historical convention, control settings on guitar amplifiers are almost invariably denoted on a ‘0’ (minimum) to ‘10’ (maximum) scale, and this convention is followed in this document.)

FIG. 10 denotes how the low frequency amplitude response of the combined power amplifier, the associated loudspeaker load, and the negative feedback network varies as the Resonance control is rotated from minimum to maximum.

It is to be noted that not all valve guitar amplifier designs utilise the application negative feedback around an audio power amplifier section. The omission of negative feedback in the power amplifier section, and the resultant significant effect on the frequency response when such a power amplifier is connected to a guitar loudspeaker system is deemed desirable by many guitarists. One example of a valve guitar amplifier with no power amplifier stage negative feedback is the VOX AC30, first produced in 1957, and still in production currently.

FIG. 11 depicts a block diagram representation of one embodiment of the present invention, comprising of an audio signal processing means to receive and process the applied audio input signal, an audio power amplifier to enable power amplification of the processed input signal, and a loudspeaker means to convert the processed and power amplified input into an acoustic output. Also depicted is a source of power to provide electrical power to the audio power amplifier and to the signal processing means.

The signal processing means may be chosen to receive an audio input in analogue form, or in a digital representation of the audio input signal, or in both forms. The form of the applied input signal is not germane to the invention.

Similarly, the signal processing means may be chosen to output an analogue signal corresponding to the processed input signal, or may output a digital representation of the processed signal input signal. The form of the processed output signal is not germane to the invention.

The audio power amplifier may be chosen to be a conventional analogue audio power amplifier, or power amplification may be achieved and implemented by pulse width modulation, duty cycle control of a high frequency carrier signal in order to improve the system power conversion efficiency. The exact means by which audio power amplification is achieved is not germane to this invention.

The power supply source for both the signal processing means, and the audio power amplifier may be derived by a conventional power line frequency laminated mains transformer, rectifier and bulk energy storage capacitors, or alternatively may implemented by high frequency switched mode techniques, offering higher power conversion efficiency, and weight and size reduction, at the expense of circuit complexity. Again, the exact nature of the means of power supply implementation is not germane to this invention.

FIG. 12 shows one means of signal processing means, whereby the input signal is received in analogue form, and converted to a digital representation of the applied analogue signal by an analogue to digital convertor. The digital representation of the input signal is then routed to a Digital Signal Processor (DSP) which acts on the numerical representation of the applied audio input, with the digitally processed signal then converted back to an analogue representation of the processed output signal for application to a subsequent power amplification means.

Also depicted in FIG. 12, is a means of digital data memory for the storage of the digital filter coefficients required for the processing of the received digital audio input signal, and the digital program instruction codes to define the processing structure. Additionally, the digital memory also allows the storage of signal processing coefficients in sets (commonly referred to as ‘patches’), so as to allow the user the provision of instantaneous selection and recall of a number of individually user defined and programmed frequency responses and amplitude distortion characteristics as may be required.

FIG. 17 illustrates a front panel selector which is connected to the digital memory so as to allow the user to select the sets of parameters and coefficients corresponding to various different output valves.

FIG. 13 illustrates in schematic format, the numerical signal flow implementation of a digital signal filter. Such a filter structure is known as an ‘Infinite Impulse Response’ (IIR) filter. In this example the structure of a second-order filter is shown. The filter structure comprises of four delay elements (denoted by the Z⁻¹ specifier), each providing a time delay equal to the input signal sampling period. Such sample period delay elements are easily implemented by the use of temporary digital data memory within the Digital Signal Processor. Two delay elements act on the input signal data path of the filter, and two delay elements act on the output signal data path of the filter. By suitable numerical scaling (or ‘weighting’) and summation of the input, delayed input and delayed output filter element terms, a digital filter can be implemented by DSP hardware and software that approximates to the response of any and all of the analogue filter functions shown in the amplifier and loudspeaker system equivalent schematic shown in FIG. 8. Current state of the art analogue to digital conversion, signal processing and digital to analogue conversion accuracy and speed is such that the deviation in amplitude and frequency response characteristics between the digital filter and the analogue filter characteristics which the digital filter has been designed to replicate are not audibly discernable.

The filter structure illustrated in FIG. 13 is for the implementation of a second order characteristic. By means of the same general arrangement of delay elements, coefficient multipliers and summations, first, second and higher order filters may be implemented on suitable signal processing hardware. Due to the finite precision by which filter coefficients can be represented by digital means, there exists an upper limit as to the order of filter that may be implemented. For the filters depicted in FIG. 8, the use of a floating point digital signal processor, with its inherent large numerical dynamic range, is easily capable of achieving the required numerical accuracy. One example of such a device is the “SHARC” (Analog Devices Inc., Norwood, Mass. USA).

The techniques for the analysis of analogue filter circuitry and topologies, the conversion of the analogue continuous time domain circuit behaviour to a discrete time domain sampled numerical implementation, and the verification and error analysis of the conversion process between continuous and discrete time systems can be easily and efficiently performed by Computer Aided Design (CAD) tools such as MATLAB and SIMULINK (Mathworks Inc.). Such CAD tools can also directly generate the filter coefficients required for the numerical algorithmic processing implementation of the desired filter responses.

Referring to FIG. 14, the numerical signal flow implementation of an amplitude domain, non-linear, harmonic distortion generating, and signal limiting, digital signal processing block is illustrated.

The absolute value of the applied system input is obtained using the identity:

For INPUT≧0, OUTPUT=INPUT

For INPUT<0, OUTPUT=−(INPUT)

By scaling the output of the absolute value process by a factor of one-half using multiplier ‘X2’, and subtracting the resultant scaled absolute value representation of the input signal from the maximum permissible full scale range of the system, a gain control coefficient is produced whose output will vary linearly from the system full scale positive value when no signal is applied to the input, to one half of the system full scale positive value when the applied input signal is of a magnitude positive or negative full scale.

By further multiplying the original input signal to the non-linear function generator with the signal resulting from the absolute value, scale and offset process just described, using multiplier ‘X1’, a system input to system output signal transfer function is obtained of the form:

Vout=Vin+(Vin²/2) for −1>Vin<0

Vout=0 for Vin=0

Vout=Vin−(Vin²/2) for 0>Vin<1

For reasons of clarity of explanation, assume the maximum positive input magnitude of the signal Vin applied to this system is bounded to +1, and the maximum negative input magnitude of the signal Vin applied to this system is bounded to −1. This would be the case implicitly for a fixed point, fractional signal processor. For a floating point processing system, the full scale positive and full scale negative input is constrained to the same fractional range by suitable choice of system input and system output scaling.

With the maximum input signal range assumed bounded to −1<Vin<1, the resultant output signal range defined by the processing equalities stated above lies between −0.5≦Vin≦0.5. This implies a system gain of one-half. However, the instantaneous gain of the system is dependent on the instantaneous magnitude of the applied input signal, with maximum system gain occurring at Vin=0. By multiplying the output of the multiplier X1 by a factor of two, the large signal, peak numerical gain of the system is restored to unity, with system gain increasing toward a value of two as the applied input signal magnitude tends towards zero. The dependence of the system incremental gain, and thus the system output, upon the magnitude of the applied input signal directly imparts an inherent non-linearity to the amplitude domain system input/output signal response.

FIG. 15 plots the system input-to-output transfer characteristic of the non-linear system just described, from minus full scale input (−1) to plus full scale (+1) input. From inspection of the plotted transfer characteristic, it is apparent that the incremental gain of the transfer function, as illustrated by the gradient of the transfer function curve, is not constant at any point throughout the bounded range of the applied input signal. As a direct consequence of this property, amplitude distortion of the applied input signal occurs in the output signal generated by the system, producing harmonic distortion components in the output signal spectrum that were not present in the original input system signal.

FIG. 16 plots the output amplitude response of the system depicted in FIG. 14 when excited by a sinusoidal input source. It can be immediately observed that at all points, apart from the specific cases where the applied input signal magnitude is zero or +/− full scale, the resultant system output magnitude is greater in magnitude than the applied input signal.

By sequentially connecting together a number, of non-linear, harmonic distortion generating processing blocks as described by FIG. 14, with the output of one block feeding the input to the subsequent non-linear processing block, the amount of instantaneous signal compression and thus the amount of harmonic distortion produced at the system process output can be defined. Each non-linear processing block adds ˜+6 dB of small-signal gain to the total system, whilst the total system large signal gain for peak input signal magnitude remains at unity. By this means the input sensitivity for a given level of total harmonic distortion can be determined and programmed by the number of serial iterations of the process described by FIG. 14 that are performed. Various sensitivity settings for prescribed levels of total harmonic distortion can be stored in the digital memory depicted in FIG. 12, for recall by the user as required. If control of distortion sensitivity in finer resolution increments than the inherent ˜6 dB resolution obtained by the addition of each discrete distortion processing block as described is required, a linear, numerical attenuation of between 0 to −6 dB can be inserted at the input to the first non-linear processing block.

Referring again to FIG. 2, it is seen that the terminal impedance of a moving coil loudspeaker increases substantially around the region of the fundamental system resonance of the combined loudspeaker drive unit and the air enclosed within the loudspeaker enclosure.

As the system impedance rises at this fundamental system resonance, the current drawn from the audio power amplifier connected to the loudspeaker, and thus the power delivery requirement from the power supply that supplies electrical energy to the said audio power amplifier also reduces, and thus the power dissipated by the loudspeaker drive unit also reduces.

Similarly, as the terminal impedance of a moving coil loudspeaker system rises at higher frequencies, due to the inductive nature of the voice coil, the power consumed by the loudspeaker system, and thus the power required to be delivered by the audio power amplifier and associated power supply source similarly reduces.

This invention exploits this fundamental reduction in the input energy requirement of a moving coil loudspeaker for a given acoustic power output, in the frequency range centred around the fundamental system resonance, and at the higher frequencies where the voice coil inductance becomes a significant part of the total loudspeaker system impedance, by increasing the maximum voltage applied to the moving coil system in a frequency selective and amplitude limited manner.

By increasing the applied terminal voltage to the loudspeaker by these frequency selective, amplitude limited means, the combined system acoustic sound pressure level may be raised, in a manner that accurately models the performance of the same loudspeaker system when connected to a traditional thermionic valve guitar amplifier.

By limiting the applied system signal input, by means of the amplitude domain, non-linear, harmonic generating means depicted in FIG. 14, and subsequently filtering the resultant limited output by means of cascaded digital IIR filter structures, each having a general structure as shown in FIG. 13, the amplitude response and frequency response of a particular combination of output valve type, loudspeaker and associated loudspeaker enclosure, may be accurately reproduced.

1. A solid state power amplifier including means for varying the output voltage in a frequency dependent manner, whereby the power output can be varied to provide a similar audible effect to that of a valve power amplifier of equivalent power rating when connected to a guitar loudspeaker system, the means for the varying the output voltage being arranged to allow for the frequency response characteristics of the loudspeaker systems, and having a non-linear amplitude domain transfer function such that the maximum power output of the amplifier is limited to at least one of (a) the rated maximum power output of its associated power supply source, and (b) the maximum rated power input of the associated loudspeaker system.

2. A solid state power amplifier according to claim 1 in which the output can be varied to produce similar effects to a valve amplifier in respect of one or more of sound pressure level characteristics, amplitude response distortion, and frequency response distortion.

3. A solid state power amplifier according to claim 1 in which the means for varying the output voltage comprises a digital signal processor.

4. A solid state audio power amplifier according to claim 1 and having a non-linear frequency response characteristic corresponding to the combination of a thermionic valve power amplifier connected to a moving coil guitar loudspeaker system.

5. A solid state audio power amplifier according to claim 1, further comprising user adjustable means for setting the low and high frequency amplitude response relative to the middle frequency amplitude response, so as to correspond to ‘Presence’ and ‘Resonance’ controls provided on thermionic valve guitar amplifiers.

6. A solid state audio power amplifier according to claim 1 and further comprising means for varying the non-linear frequency response characteristic, so as to allow the recreation of the frequency response attributes of various different thermionic output valve types.

7. A solid state audio power amplifier according to claim 1 and further comprising means for varying the non-linear frequency response characteristic, so as to allow the recreation of the tonal attributes of various different moving coil loudspeaker types and their associated loudspeaker enclosures.

8. A solid state audio power amplifier according to claim 1 and further comprising means for varying the non-linear amplitude system input to system output transfer function, so as to allow the recreation of the harmonic distortion attributes of various different thermionic output valve types.

9. A solid state audio power amplifier according to claim 1 and further comprising means to control and reduce, the maximum power output level before the onset of a required degree of amplitude distortion becomes audible.

10. A solid state power amplifier according to claim 2 including means for storing sets of digital signal processing parameters and coefficients in digital memory so as to represent a range of harmonic distortion attributes of various different thermionic output valve types, the non-linear frequency response characteristics of various different moving coil loudspeaker types and their associated loudspeaker enclosures, and the desirable ‘Presence’ and ‘Resonance’ tonal adjustments.

11. A solid state amplifier according to claim 2, including means for storing sets of digital signal processing parameters and coefficients in digital memory, so as to represent a range of harmonic distortion attributes of various different thermionic output valve types, the non-linear frequency response characteristics of various different moving coil loudspeaker types and their associated loudspeaker enclosures, and the desirable ‘Presence’ and ‘Resonance’ tonal adjustments; and further comprising means for recalling sets of stored digital signal processing parameters and coefficients to enable the selection of any desired combination of harmonic distortion attributes of various different thermionic output valve types.

12. A solid state amplifier according to claim 2, including means for storing sets of digital signal processing parameters and coefficients in digital memory, so as to represent a range of harmonic distortion attributes of various different thermionic output valve types, the non-linear frequency response characteristics of various different moving coil loudspeaker types and their associated loudspeaker enclosures, and the desirable ‘Presence’ and ‘Resonance’ tonal adjustments, and further comprising means for recalling sets of stored digital signal processing parameters and coefficients to enable the selection of any desired combination of harmonic distortion attributes of various different thermionic output valve types, in which the means for recalling the digital signal processing parameters and coefficients comprises a user adjustable hardware control selector connected to digital memory means whereby the attributes of the different thermionic output valves can be selected.

13. A solid state power amplifier according to claim 3 in which the digital signal processor includes IIR filters.
